(19) United States
(12) Patent Application Publication
(10) Pub. No.: US 2025/0167510 A1
(43) Pub. Date: May 22, 2025

(54) ACCOMMODATING VARIOUS LASER DIODE EMITTER AND IMAGING SPOT SIZES FOR LASER DISPLAYS USING BEAM SHAPING OPTICS

(71) Applicant: Prysm Systems, Inc., Milpitas, CA (US)

(72) Inventor: Roger A. HAJJAR, San Jose, CA (US)

(73) Assignee: Prysm Systems, Inc., Milpitas, CA (US)

(21) Appl. No.: 18/953,374

(22) Filed: Nov. 20, 2024

Related U.S. Application Data
(60) Provisional application No. 63/600,983, filed on Nov. 20, 2023.

(51) Int. Cl. H01S 5/02253; B81B 7/02

(52) U.S. Cl. CPC H01S 5/02253; B81B 7/02; B81B 2201/042

(57) ABSTRACT

Lenses can be used to compact and/or shape a beam of light from any variable multimode light source such as a laser that has a larger beam footprint. The lenses are a cylindrical or toroidal pair that is disposed between any magnification lenses and the screen so that the magnified light beam can be appropriately directed to the screen. The lenses are different from magnification lenses in that the lens pair does not magnify the light beam, but rather, adjusts in the single mode (SM) direction and one dimension in the multimode (MM) direction. One of the lenses of the lens pair is negative while the other lens is positive. In so doing, then lens pair provides the light beam in a focal point on a non-uniform two-dimensional portion of the screen.

### CROSS-REFERENCE TO RELATED APPLICATIONS

This application claims benefit of U.S. Provisional Patent Application Ser. No. 63/600,983, filed Nov. 20, 2023, which is herein incorporated by reference.

### BACKGROUND OF THE DISCLOSURE

### Field of the Disclosure

Embodiments of the present disclosure generally relate to shaping a beam emitted by a multimode light source.

### Description of the Related Art

In laser phosphor displays, multimode lasers are oftentimes used to obtain higher laser diode power to produce a brighter display. The emitted laser beam footprint when impinging on a phosphor screen is typically elliptical with less than 1 width to height ratio whereby the narrow width scans in the direction perpendicular to red-green-blue (RGB) stripes. Each stripe is typically ⅓ the width of the total RGB pattern, and the RGB stripes could be deposited with diffusive material such as phosphor or quantum dots.

The laser diode emitter has two dimensions. One dimension in the single mode (SM) direction and one dimension in the multimode direction. The direction in the multimode (MM) direction sets the light beam height on the screen while the single mode is the beam width that is used to scan in the RGB (i.e., mostly perpendicular) direction. The laser diode emitter is typically imaged on the screen through an optical system with a magnification M.

If the laser diode emitter is 1×7 um for example, and M is 100, the beam footprint/size on the screen is 100×700 um. The laser diode emitter and magnification works well if the pixel RGB is 720 um where each RGB stripe is 240 um (i.e., 720/3). The beam height of 700 um is about 720 um so the beam footprint fits well with a pixel that is mostly square (i.e., 720×700). However, in order to obtain more power, the laser diode emitters increase in height from, for example, 7 um to 15 um. Keeping the same M value of 100 produces a beam that is 1500 um on the screen which violates the 720 um requirement. Hence, there needs to be two magnifications. One magnification is in the single mode direction (Msm) in the SM direction and a separate magnification in the MM direction (Mmm). In such a case, Msm equal to 100 and Mmm equal to 50 would render a 100 um×750 um footprint.

The image on the screen is formed by scanning in theta X and theta Y to form an image of X and Y dimensions on the screen. As a result of scanning, the laser diode beam rotates in the corners. The rotating is due to a compound angle or byproduct in X and Y angles causing the beam not to be vertical as the beam scans. The beam actually tilts as the beam scans. For example, with M equal to 100, the 100×700 um beam tilts by 9 degrees from the center scan area where there is no tilt or 0 degrees. The angular tilt causes the effective width of the beam to be larger than 100 um by the projected beam height x cosine tilt angle. The larger effective width of the beam in turn causes RGB or color crosstalk. Reducing the height of the beam form 700 um to 350 um as an example reduces the effective beam width and hence crosstalk when higher panel resolution is desired. The circularization of the beam footprint addresses the issue as well. In the case of the 1×15 um laser diode, the desires is for Msm to be equal to 100 and Mmm to be equal to 25 in order to target a shorter sport size. However, the pixel is not square anymore. The non-square pixel is addressed by increasing the number of scan lines in the vertical direction in order to increase the fill factor or black gap between the lines.

Therefore, there is a need in the art for a variable multimode laser system.

### SUMMARY OF THE DISCLOSURE

Lenses can be used to compact and/or shape a beam of light from any variable multimode light source such as a laser that has a larger beam footprint. The lenses are a cylindrical or toroidal pair that is disposed between any magnification lenses and the screen so that the magnified light beam can be appropriately directed to the screen. The lenses are different from magnification lenses in that the lens pair does not magnify the light beam, but rather, adjusts in the single mode (SM) direction and one dimension in the multimode (MM) direction. One of the lenses of the lens pair is negative while the other lens is positive. In so doing, then lens pair provides the light beam in a focal point at the screen.

In one embodiment, a display system comprises: a light source; a display screen; a magnification lens disposed between the light source and the display screen; and a cylindrical or toroidal lens pair disposed between the magnification lens and the screen, wherein a first lens of the cylindrical or toroidal lens pair is a negative cylindrical or toroidal lens capable of adjusting a first dimension of magnification in an X direction of an X-Y plane, and wherein a second lens of the cylindrical or toroidal lens pair is a positive cylindrical or toroidal lens capable of adjusting a second dimension of magnification in a Y direction of the X-Y plane.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a perspective schematic diagram of a display system according to implementations described herein

FIG. 2 is a schematic illustration of a microelectromechanical (MEMS) acting as an aperture focusing a light beam according to one embodiment.

FIG. 3 is a schematic illustration of a laser diode emission profile characterized by two orthogonal divergent angles according to one embodiment.

FIG. 4 is a schematic illustration of a single lens imaging system between a laser diode and a scanning area according to one embodiment.

FIG. 5 is a schematic illustration of a spot size in an imaging plane according to one embodiment.

FIG. 6 is a schematic illustration of a magnification lens system according to one embodiment.

FIG. 7 is a schematic illustration of a magnification lens system according to another embodiment.

FIG. 8 is a schematic illustration of an optical beam expansion or magnification technique of a multimode light beam according to one embodiment.

FIG. 9 is a schematic illustration of a display system using a cylindrical lens pair according to one embodiment.

FIG. 10 is a schematic illustration of a display system using a cylindrical lens pair according to another embodiment.

FIG. 11 is a schematic illustration of a lens pair according to one embodiment.

FIG. 12 is a schematic illustration of a lens pair according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

Lenses can be used to compact and/or shape a beam of light from any variable multimode light source such as a laser that has a larger beam footprint. The lenses are a cylindrical or toroidal pair that is disposed between any magnification lenses and the screen so that the magnified light beam can be appropriately directed to the screen. The lenses are different from magnification lenses in that the lens pair does not magnify the light beam, but rather, adjusts in the single mode (SM) direction and one dimension in the multimode (MM) direction. One of the lenses of the lens pair is negative while the other lens is positive. In so doing, then lens pair provides the light beam in a focal point on a non-uniform two-dimensional portion of the screen.

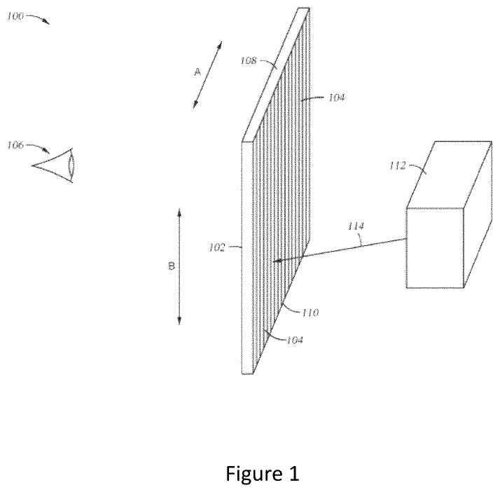

FIG. 1 is a perspective schematic diagram of a display system 100, according to certain embodiments. Display system 100 is a light-based electronic display device configured to produce video and static images for a viewer 106. The display system 100 includes light-emitting phosphors 104 disposed between two planes. For example, display system 100 may be a LPD or other phosphor-based display device. While shown as a single image panel 102 in FIG. 1, it is to be understood that the image panel 102 may include a plurality of image panels seamlessly coupled together. For example, the image panel 102 may comprise one or more protective front plane panels and one or more image panel portions with a plurality of phosphors 104 coupled therebetween. FIG. 1 shows a plurality of phosphors 104 extending from the top 108 of the image panel 102 to the bottom 110 of the image panel 102.

The display system 100 includes a light source 112, such as a laser module, that is used to produce one or more scanning light beams 114, such as laser beams, to excite the phosphors 104 in image panel 102. The phosphors 104 are stripes that are made up of alternating phosphor material of different colors, e.g., red, green, and blue, where the colors are selected so that they can be combined to form white light and other colors of light. Scanning light beam 114 is a modulated light beam that includes optical pulse width and/or amplitude variable pulses that carry image information and is scanned across image panel 102 along two orthogonal directions, e.g., horizontally (parallel to arrow A) and vertically (parallel to arrow B), in a raster scanning pattern to produce an image on image panel 102 for viewer 106. In some embodiments, scanning light beam 114 includes visible lasers beams of one or more colors that discretely illuminate individual subpixels of the phosphors 104 to produce an image. The scanning light beam 114 can be of a specific width and height, so as to excite only a specific phosphor 104 or group of phosphors 104 at one time, such as a scanning laser beam, which is approximately 700 μm tall and approximately 100 μm wide. A feedback control alignment mechanism can be provided in the display system 100 to maintain proper alignment of the scanning beam 114 on the desired sub-pixel to achieved desired image quality.

In laser scanning systems, the laser diode (LD), typically a semiconductor diode with a Gaussian light emission profile, is imaged and scanned on plane using an optical system comprising of lenses and scanning mirrors. The scanning is typically done with a moving mirror(s) that are angularly activated in a bipolar fashion ±θₓ (to achieve a horizontal line of dimensions ±X) and ±θ_{y} (to achieve a vertical line of dimensions ±Y). The scanning is typically a raster scan meaning one dimension (usually horizontal X) is scanned at much faster than the vertical resulting in a scan area of dimensions 2X by 2Y. The LD is directly current modulated to form the desired video image or pattern. The geometric distance L from the mirror(s) to the normal of the scanning image area and the angular magnitude ±θₓ and ±θ_{y}, determine the dimensions of the scan area of 2X by 2Y. For example, if the distance L=115 mm and the mechanical angular magnitude of the horizontal mirror is ±θₓ=±10 degrees, the resulting scan line is:

$$\pm X = L . tan ( \pm 2 θ x )$$

$$\pm X = \pm 42 mm$$

While the angular scan magnitude set the line width, the size of the mirror sets the numerical aperture (NA) of the system in the imaging space which determines the resolution of the system. Typically, the mirror is a micro-electro-mechanical-system or MEMS and has a diameter D=1 mm. The goal is to ensure the LD light is focused near the scanning area while reflected off the MEMS and does not fall off outside the MEMS area.

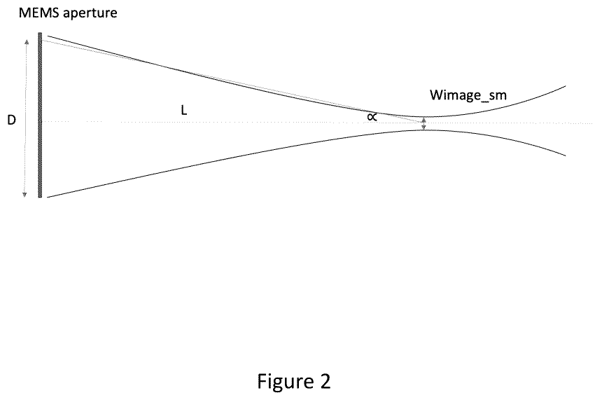

FIG. 2 is a schematic illustration of a microelectromechanical (MEMS) acting as an aperture focusing a light beam according to one embodiment. FIG. 2 illustrates how the MEMS acts as the systems aperture focusing the beam at a distance L with the subtended focus angle α shown to be derived as:

$$α = inv sin ( \frac{D}{2 L} )$$

$$D = 1 mm , L = 15 mm : α = 0.0 \; 043 rad$$

Refer the spot size at best focus to be Wimage_sm (assuming Gaussian propagation) is approximately:

$$W image\_sm = \frac{2 λ}{α \prod }$$

For λ=400 nm, Wimage_sm=60 um or the spot diameter cannot be smaller than about 60 um limited by D and L.

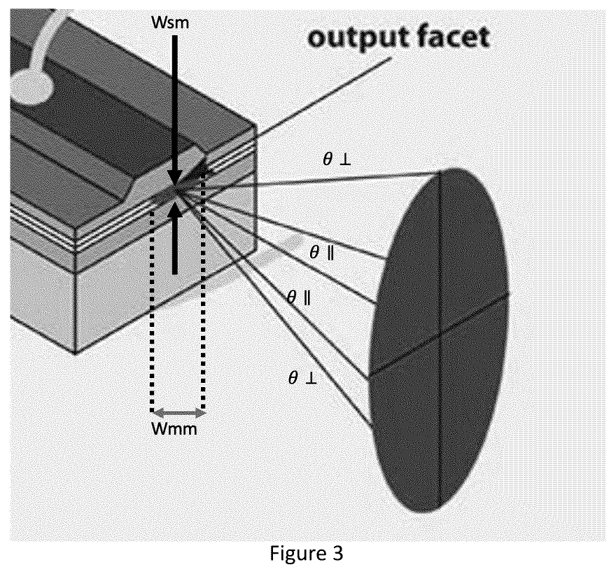

It is important to use the MEMS as the principal aperture when imaging the LD onto the scan area. FIG. 3 is a schematic illustration of a laser diode emission profile characterized by two orthogonal divergent angles according to one embodiment. The LD has an emission profile that is characterized by two orthogonal divergence angles as shown in FIG. 3. The light intensity of the LD follows a Gaussian distribution. The half angles 1/e²θ⊥ and θ// determine the point at which 86% of the total power is emitted by the LD. The LD is a waveguide of a certain length (typical 1 mm) that is terminated at the facet with two physical dimensions shown below as Wsm and Wmm.

The Wsm dimension is perpendicular to the junction and emits a single mode of light. The light emitted from Wsm has an angular emission of half divergence angle θ⊥. For example, a 405 nm LD has a typical 01 of 24 deg. The wavelength controls the waveguide size in the SM direction which controls the perpendicular divergence angle. An example is an infrared laser(eg 830 nm) that has a lower divergence angle (e.g., 17 degrees) than a Violet laser (eg 405 nm) (e.g., 24 degrees). One can use the angle θ⊥ to derive Wsm using Gaussian optics:

$$Wsm = \frac{2 λ}{θ ⊥ \prod }$$

$$Wsm = 0.6 um$$

We have now established that the LD source size is 0.6 um. Given that the best possible spot size at the imaging plane is Wimage_sm is 60 um (limited by the MEMS size). The ratio of image to object size is the total system magnification:

$$M system = \frac{W image\_sm}{W s m}$$

$$M system = 100$$

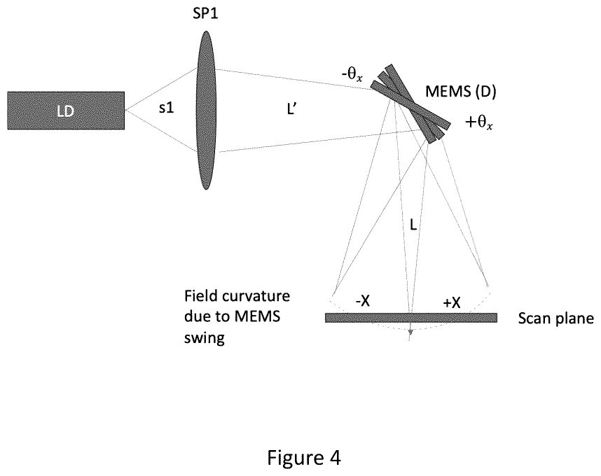

This system magnification of 100 is required for best imaging of the LD onto the scanning surface. FIG. 4 is a schematic illustration of a single lens imaging system between a laser diode and a scanning area according to one embodiment. Assuming an ideal single lens imaging system between the LD and the scanning area is shown in FIG. 4. The LD is imaged onto the scanning surface with a spherical lens SP1, the distance of SP1 of focal length f1 from the LD is s1 and the distance of SP1 from the scanning area is s1′, whereby s1′ is composed of the distance from SP1 to the MEMS mirror L′ and the distance from the MEMS to the scanning area L. Therefore, s1′ (image coordinate) and s1 (object coordinate) meet the requirement:

$$\vert M system \vert = \frac{s {1}^{′}}{s 1}$$

$$\vert M system \vert = 100$$

$$s {1}^{′} = 100 s 1$$

Whereby:

$$\frac{1}{f 1} = \frac{1}{s 1} + \frac{1}{s {1}^{′}}$$

$$f 1 = \text{.99} s 1$$

$$for f 1 = 2.5 mm , s 1 = 2.47 mm , s {1}^{′} = 247 mm$$

$${L}^{′} = s {1}^{′} - L$$

$${L}^{′} = 132 mm$$

The system in FIG. 4 uses an ideal lens SP1. Lens designs should consider using a combination of two lenses such as a first aspheric lens that can accept a high numerical aperture (a positive lens with higher order conic components and a short focal length) and a second weaker positive lens with a long focal length in order to ensure lowest aberrations as well as to compensate for focus setting of the first lens with the second lens. The aspherical lens produces a virtual image of the LD (LD source is less than the focal length of the aspheric) and the spherical lens images the virtual image of the LD onto the scan plane.

Another consideration for SP1 is the use of a combination of two lenses, a first positive lens with a short focal lens followed by an achromatic lens (negative-positive cemented doublet with a high and low dispersive glass materials) in order to correct for wavelength dispersion of the LD as well as other aberrations.

The lens designs discussed above satisfy the imaging requirement for the single mode of the LD. Laser diodes are produced with different emitter sizes in the direction parallel to the junction. The emitter size parallel to the junction is defined by the LD architecture to produce higher optical power by emitting several points of light known as modes. The emitter size parallel to the junction Wmm is larger than Wsm as shown in FIG. 3.

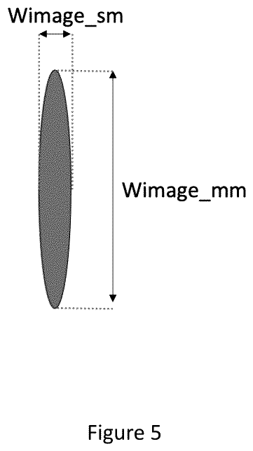

Typically, Wmm varies in sizes from about 3 um to more than 15 um (which is much larger than Wsm of 0.6 um). The larger the Wmm, the higher the output power of the LD (with higher electrical current). It is desired in displays or other laser-based applications to have higher laser power. However, the spot size in the imaging plane (i.e. after SP1) becomes highly elliptical or asymmetric in width and height as shown in FIG. 5. FIG. 5 is a schematic illustration of a spot size in an imaging plane according to one embodiment.

Given the system magnification Msystem is 100, Wimage_mm scales as 100×Wmm. For example, if Wmm=15 um, the spot height on the imaging plane is Wimage_mm=1500 um (whereas Wimage_sm is only 60 um). A large spot height affects the resolution in the Y direction. It is also observed that the spot rotates as a byproduct of the X and Y scanning (by as much as 15 degrees). This in turn increases the effective width of the spot in the X direction (also adversely impacting resolution).

Reducing the spot height on the imaging plane is achieved by scaling the beam in the multimode direction without affecting the single mode direction. This is done using a pair of cylindrical or toroidal lenses that have power in the parallel junction direction and no optical power in the perpendicular junction direction. The goal is to modify the system magnification in the multimode direction by expanding the beam. The multimode direction barely fills the MEMS mirror diameter because its low divergent angle θ// typically less than 15 deg and often less than ½ of θ⊥ in the single mode direction.

The parallel to the junction divergence angle is always much smaller than perpendicular. The WSM is narrow in size (e.g., 0.6 um) and hence acts like a point source with a wide emission angle while the Wmm is wide (e.g., 10-15 um) and emits lower angle of light as if collimated. In the parallel case, there is no dependence on wavelength as the beam looks like a large window of light. The perpendicular dimension controls the wavelength. Therefore, there is margin to increase the beam diameter in the multimode direction which effectively reduces the spot height on the imaging plane.

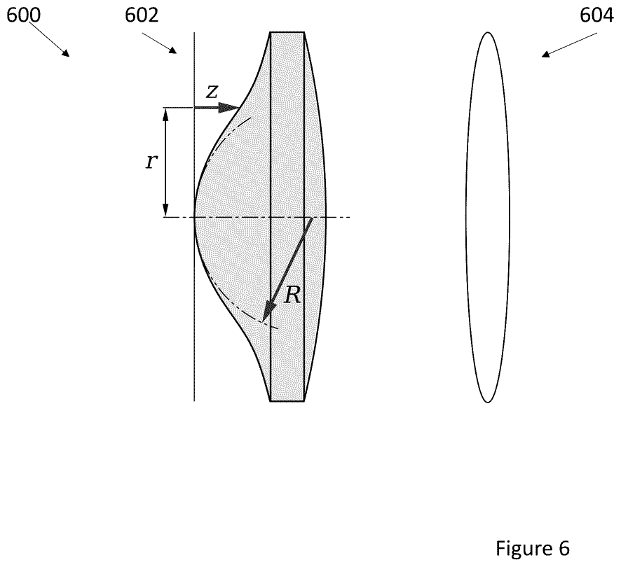

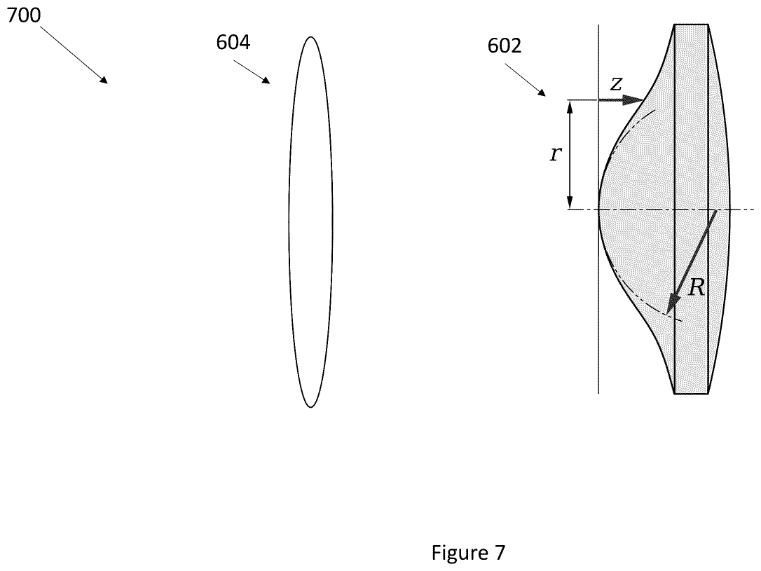

FIG. 6 is a schematic illustration of a magnification lens system 600 according to one embodiment. The system 600 includes an aspheric lens 602 and a positive lens 604. The aspheric lens 602 is shown on the left and is thus positioned closer to the light source than the positive lens 604. FIG. 7 is a schematic illustration of a magnification lens system 700 according to another embodiment. In system 700, the positive lens 604 is shown on the left and is thus positioned closer to the light source than the aspheric lens 602. The aspheric lens 602 has a radius of curvature R and an optical axis in the z direction spaced a distance r from the center axis.

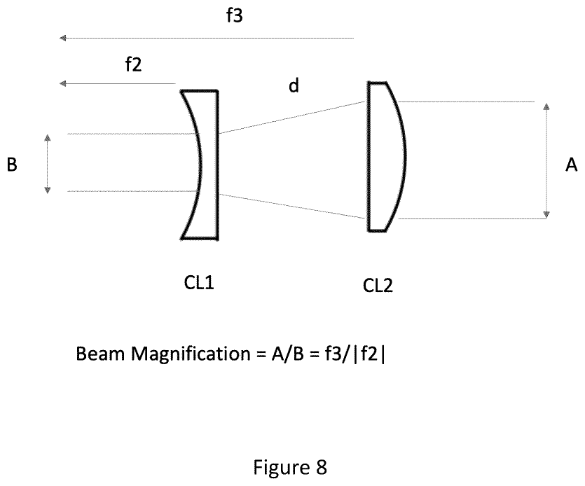

FIG. 8 is a schematic illustration of an optical beam expansion or magnification technique of a multimode light beam according to one embodiment. An illustration in FIG. 8 shows optical beam expansion or magnification technique of the multimode beam by 2×. f2 is the focal length of the first negative cylindrical lens CL1 and f3 is the focal length of the second positive cylindrical lens CL2. The separation d between f3 and f2 that will result in a beam expansion:

$$Beam Magnification = \frac{f 3}{\vert f 2 \vert}$$

$$f 3 - \vert f 2 \vert = d$$

$$when f 3 = 2 \vert f 2 \vert ,$$

$$d = \vert f 2 \vert$$

The resulting magnification of the imaging spot in the multimode direction is:

$$\vert M {system}_{mm} \vert = \vert M system \vert \times \vert M 2 \vert \times \vert M 3 \vert$$

$$where , \vert M 2 \vert = \frac{s {2}^{′}}{s 2}$$

$$and , \vert M 3 \vert = \frac{s {3}^{′}}{s 3}$$

With,

$$\frac{1}{f 2} = \frac{1}{s 2} + \frac{1}{s {2}^{′}}$$

$$\frac{1}{f 3} = \frac{1}{s 3} + \frac{1}{s {3}^{′}}$$

The insertion of CL1 and CL2 pair in the optical scanning system of FIG. 4 has to follow certain criteria. The position of CL1 relative to SP1 is p1 and the distance between CL1 and CL2 is p2.

The object coordinate of CL1 s2=−(s1′-p1)

Given f2, one solves for s2′

The object coordinate s3=|s2′|+p2 and the image coordinate s3′=|s2|-p2

Assume p2=|f2|, solve for f3. f3 should be roughly 2|f2| per above.

Example, setting f2=−5 mm and using s1′=247 mm (calculated above) leads to f3=9.69 mm which is about 2|f2|. The corresponding magnifications using the equations above are:

$$M 2 = 0.021$$

$$M 3 = 23.45$$

$$M system\_multimode = 49.5$$

$$Spot height = 15 um \times 49.5 = 7.42 um$$

Repeating the same with 4X beam expansion,

$$f 3 = 4 \vert f 2 \vert$$

$$f 3 - \vert f 2 \vert = d$$

$$\vert f 2 \vert = \frac{d}{3}$$

Example, setting f2=−5 mm and using s1′=247 mm (calculated above) with p2=d=3|f2| leads to f3=18.47 mm which is about 4|f2|. The corresponding magnifications using the equations above are:

$$M 2 = 0.021$$

$$M 3 = 11.29$$

$$M system\_multimode = 23.81$$

$$Spot height = 15 um \times 23.81 = 357 um$$

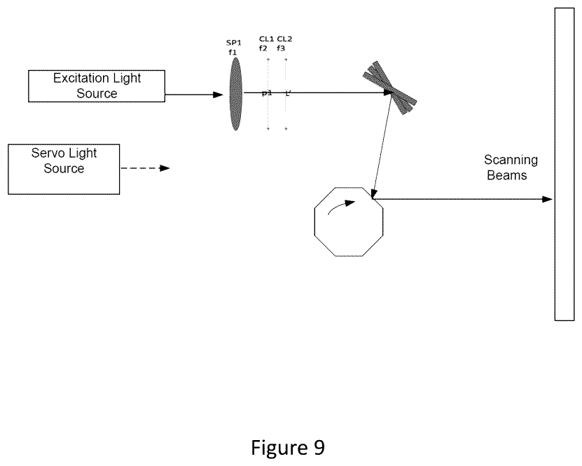

FIG. 9 is a schematic illustration of a display system using a cylindrical lens pair according to one embodiment. FIG. 9 shows the insertion of the cylindrical pair as part of the optical scanning system in order to magnify the beam in the multimode direction. Note that the lenses shown are ideal (i.e. no thickness). A design using an optical CAD model is recommended to tune the focal length and separation taking into account the thicknesses of the lenses. However, the general design principle applies.

Another consideration is to use a high index dispersive glass for the negative cylindrical lens CL1 and lower index less dispersive glass for the positive cylindrical lens CL2. This combination will help in achromatic dispersion due to wavelength linewidth or wavelength change of the LD.

Given that emitter width is changing with new lasers (i.e., the multimode direction), cylindrical lens can be used to change the magnification to accept different emitter widths. For example, a 1×7 um laser diode imaged on a plane at 100 um×350 um means magnification is 100× in the SM direction and 50× in the MM direction. Similarly, a 1×15 um laser diode imaged on a plane at 100 um×350 um means the magnification is 100× in the SM direction and 23× in the MM direction (assuming the beam in MM direction does not overfill the MEMS physical diameter as it becomes the limiting aperture for the MM direction). The cylindrical lenses allows changing the magnification factor by changing the focal length ration between the first and second lens. For example, with no cylindrical lens, there is 100× for both SM and MM and hence a 1×7 um laser is imaged at 100 um×700 um spot size.

A pair of cylindrical lenses, however, shorten the spot height. With a pair of cylindrical lenses where the first lens has a field of curvature (fc) of −3 mm (i.e., negative) and where the second lens has an fc of 6 mm (i.e., positive), the magnification of the beam is increased by 2X in the MM direction 6/|−3|=2×, and the post size is decreased 2X in the MM direction. Hence, the system magnification is 50× versus 100× in the MM direction. The power of the cylindrical lenses can be adjusted to change the beam size magnification depositing on the focal length ratio.

Given a laser spot size that should have a focal point on a non-uniform two-dimensional portion of a target plane, and should be reflected off at least one pivoting (or rotating) micro mirror, whose reflective area is fixed and small in relation to the emitted spot size, and whose emission from the light source should be magnified to cover the intended target plane portion, and whose emission spot from the light source should be anisotropic, where the ratio of the emission beam source is different from the ratio of the target portion of the plane, but where the width of the beam should be smaller than the width of the target portion area of the plane, a lens pair is used. The lens pair is cylindrical and placed after a magnification lens. The lens pair comprises a negative cylindrical lens and a positive cylindrical lens. The lenses adjust one dimension magnification of the beam spot from the other dimension.

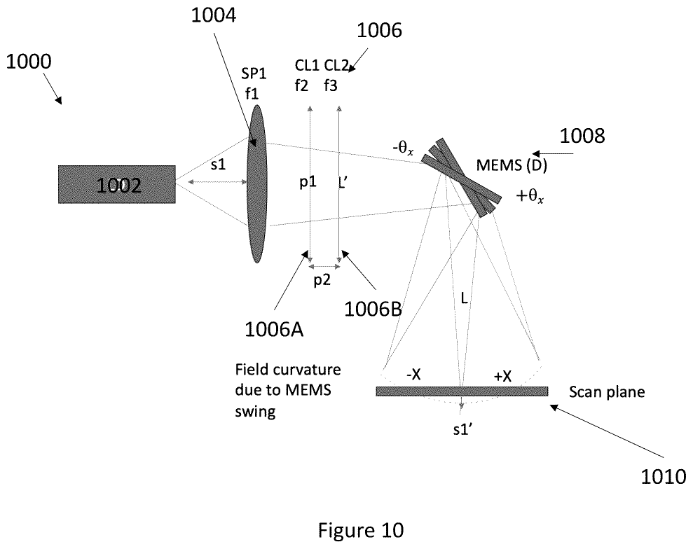

FIG. 10 is a schematic illustration of a display system 1000 using a cylindrical lens pair according to another embodiment. The system 1000 includes a light source 1002 such as a laser diode, a magnification lens system 1004, a lens pair 1006, a MEMS device 1008, and a scan plane 1010. The lens pair 1006 includes a first lens 1006A (labeled CL1 for cylindrical lens 1) and a second lens 1006B (labeled CL2 for cylindrical lens 2) where the first lens 1006A is disposed between the second lens 1006B and the magnification lens system 1004. Similarly, the second lens 1006B is disposed between the first lens 1006A and the MEMS device 1008. The MEMS device 1008 pivots between −θₓ and +θₓ. Light, such as laser beam from light source 1002, is imaged onto the scan plane 1010 with a spherical lens SP1 as the magnification lens system 1004. As shown in FIG. 10, the magnification lens system 1004 is a single positive lens that magnifies the light beam, but it is to be understood that other magnification lenses are possible such as shown in FIGS. 6 and 7. The magnification lens 1004 has a focal length f1 and is spaced from the light source 1002 by a distance S1. S1′ is composed of the distance L′ from the magnification lens system 1004 to the MEMS device 1008 and the distance L from the MEMS device 1008 to the scan plane 1010. The lens pair 1006 is spaced from the magnification lens system 1004. Specifically, the first lens 1006A has a focal length f2 and is spaced a distance p1 from the magnification lens system 1004. The second lens 1006B has a focal length f3 and is spaced from the first lens 1006A by a distance p2. The light is exposed to the scan plane 1010 at −X through +X distances from the center of the scan plane 1010. It is to be understood that while cylindrical lens are used in the description, toroidal lenses are also contemplated for the lens paid. Furthermore, a mixture of cylindrical and toroidal lenses is also contemplated where the first lens 1006A may be either a cylindrical or toroidal lens, and the second lens 1006B may be either a cylindrical or toroidal lens.

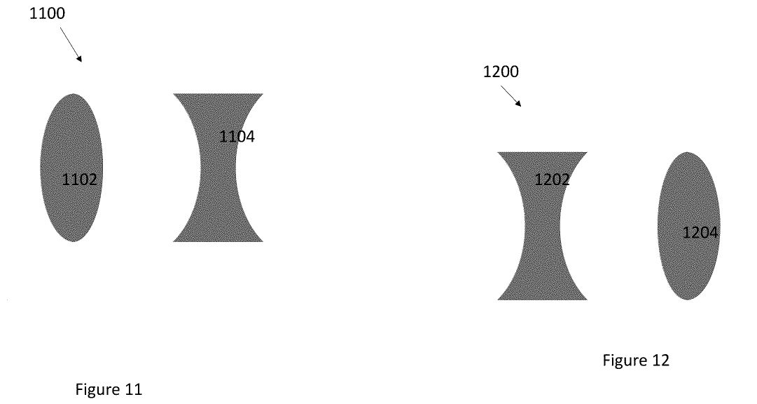

FIG. 11 is a schematic illustration of a lens pair 1100 according to one embodiment. FIG. 12 is a schematic illustration of a lens pair 1200 according to another embodiment. Each lens pair 1100, 1200 includes a positive lens 1102, 1204 and a negative lens 1104, 1202. For lens pair 1100, the positive lens 1102 is arranged to be disposed between the negative lens 1104 and the light source while the negative lens 1104 is arranged to be disposed between the positive lens 1102 and the screen. For lens pair 1200, the negative lens 1202 is arranged to be disposed between the positive lens 1204 and the light source while the positive lens 1204 is arranged to be disposed between the negative lens 1202 and the screen.

By using a lens pair between a magnification lens system and the screen, compact and/or shape a beam of light from any variable multimode light source such as a laser that has a larger beam footprint is obtained.

In one embodiment, a display system comprises: a light source; a display screen; a magnification lens disposed between the light source and the display screen; and a cylindrical or toroidal lens pair disposed between the magnification lens and the screen, wherein a first lens of the cylindrical or toroidal lens pair is a negative cylindrical or toroidal lens capable of adjusting a first dimension of magnification in an X direction of an X-Y plane, and wherein a second lens of the cylindrical or toroidal lens pair is a positive cylindrical or toroidal lens capable of adjusting a second dimension of magnification in a Y direction of the X-Y plane. The first lens is disposed between the second lens and the magnification lens. The first lens has a field curvature (fc) of between about 5 mm and about −2 mm. The second lens has a field curvature (FC) of between about 4 mm and about 20 mm. The lens pair is configured to reduce a spot size of light passing through the magnification lens from the light source by a factor of about 2. The display system further comprises one or more microelectromechanical system (MEMS) mirrors disposed between the lens pair and the display screen. The first lens has a first focal length, wherein the second lens has a second focal length, and wherein the first lens and spaced from the second lens by a distance equal to a difference between the second focal length and an absolute value of the first focal length. The first lens has a first index of refraction, wherein the second lens has a second index of refraction, and wherein the first index of refraction is greater than the second index of refraction. The magnification lens is configured to increase magnification by an amount and wherein the lens pair is configured to decrease a spot size by the amount in a multimode direction. The lens pair is configured to have a beam of light enter the first lens as a first beam width and exit the second lens at a second beam width. The beam has a magnification equal to the second width divided by the first width. The first lens has a first focal length, wherein the second lens has a second focal length, and wherein the magnification is equal to the second focal length divided by an absolute value of the first focal length. The light source is a laser diode. The magnification lens comprises a first magnification lens and a second magnification lens. The first magnification lens is an aspheric lens. The second magnification lens is a positive lens and is disposed between the first magnification lens and the lens pair. The first magnification lens is a positive lens. The second magnification lens is an achromatic lens and is disposed between the first magnification lens and the lens pair. The display system further comprises a raster polygon. The display system further comprises a servo light source separate and distinct from the light source.

While the foregoing is directed to embodiments of the present disclosure, other and further embodiments of the disclosure may be devised without departing from the basic scope thereof, and the scope thereof is determined by the claims that follow.

What is claimed is:

1. A display system, comprising:
a light source;
a display screen;
a magnification lens disposed between the light source and the display screen; and
a cylindrical or toroidal lens pair disposed between the magnification lens and the screen, wherein a first lens of the cylindrical or toroidal lens pair is a negative cylindrical or toroidal lens capable of adjusting a first dimension of magnification in an X direction of an X-Y plane, and wherein a second lens of the cylindrical or toroidal lens pair is a positive cylindrical or toroidal lens capable of adjusting a second dimension of magnification in a Y direction of the X-Y plane.

2. The display system of claim 1, wherein the first lens is disposed between the second lens and the magnification lens.

3. The display system of claim 1, wherein the first lens has a field curvature (fc) of between about 5 mm and about −2 mm.

4. The display system of claim 1, wherein the second lens has a field curvature (FC) of between about 4 mm and about 20 mm.

5. The display system of claim 1, wherein the lens pair is configured to reduce a spot size of light passing through the magnification lens from the light source by a factor of about 2.

6. The display system of claim 1, further comprising one or more microelectromechanical system (MEMS) mirrors disposed between the lens pair and the display screen.

7. The display system of claim 1, wherein the first lens has a first focal length, wherein the second lens has a second focal length, and wherein the first lens and spaced from the second lens by a distance equal to a difference between the second focal length and an absolute value of the first focal length.

8. The display system of claim 1, wherein the first lens has a first index of refraction, wherein the second lens has a second index of refraction, and wherein the first index of refraction is greater than the second index of refraction.

9. The display system of claim 1, wherein the magnification lens is configured to increase magnification by an amount and wherein the lens pair is configured to decrease a spot size by the amount in a multimode direction.

10. The display system of claim 1, wherein the lens pair is configured to have a beam of light enter the first lens as a first beam width and exit the second lens at a second beam width.

11. The display system of claim 10, wherein the beam has a magnification equal to the second width divided by the first width.

12. The display system of claim 11, wherein the first lens has a first focal length, wherein the second lens has a second focal length, and wherein the magnification is equal to the second focal length divided by an absolute value of the first focal length.

13. The display system of claim 1, wherein the light source is a laser diode.

14. The display system of claim 1, wherein the magnification lens comprises a first magnification lens and a second magnification lens.

15. The display system of claim 14, wherein the first magnification lens is an aspheric lens.

16. The display system of claim 15, wherein the second magnification lens is a positive lens and is disposed between the first magnification lens and the lens pair.

17. The display system of claim 14, wherein the first magnification lens is a positive lens.

18. The display system of claim 17, wherein the second magnification lens is an achromatic lens and is disposed between the first magnification lens and the lens pair.

19. The display system of claim 1, further comprising a raster polygon.

20. The display system of claim 1, further comprising a servo light source separate and distinct from the light source.
